(19) United States
(12) Patent Application Publication
(10) Pub. No.: US 2026/0363103 A1
(43) Pub. Date: Nov. 12, 2026

(54) WIRING SUBSTRATE AND SEMICONDUCTOR PACKAGE INCLUDING THE SAME

(71) Applicant: SAMSUNG ELECTRONICS CO., LTD., Suwon-si (KR)

(72) Inventors: YUKYUNG PARK, Suwon-si (KR); YOUNG LYONG KIM, Suwon-si (KR); Hyeonjae KIM, Suwon-si (KR)

(73) Assignee: SAMSUNG ELECTRONICS CO., LTD., Suwon-si (KR)

(21) Appl. No.: 19/441,318

(22) Filed: Jan. 6, 2026

(30) Foreign Application Priority Data
May 9, 2025 (KR) 10-2025-0060645
Jun. 24, 2025 (KR) 10-2025-0083426

(51) Int. Cl. H10W 70/63; H10W 70/60; H10W 70/685; H10W 74/10; H10B 80/00; H10D 80/20; H10D 80/30; H10W 74/15; H10W 90/00; H10W 90/10

(52) U.S. Cl. CPC H10W 70/63; H10W 70/611; H10W 70/685; H10W 74/117; H10B 80/00; H10D 80/215; H10D 80/30; H10W 74/15; H10W 90/10; H10W 90/724

(57) ABSTRACT

A wiring substrate includes a first redistribution layer; a first core layer; a second core layer; and a second redistribution layer, which are sequentially stacked; a first capacitor on a first surface of the first core layer; and a second capacitor on a first surface of the second core layer, in which the first core layer comprises a first via, which penetrates the first core layer and is connected to the first redistribution layer, in which the second core layer comprises a second via, which penetrates the second core layer and is connected to the second redistribution layer, in which the first via and the second via are in contact with each other between the first core layer and the second core layer, in which the first capacitor is in a first recess, which is in the first surface of the first core layer.

### CROSS-REFERENCE TO RELATED APPLICATIONS

This U.S. non-provisional patent application claims priority under 35 U.S.C. §119 to Korean Patent Application Nos. 10-2025-0060645 and 10-2025-0083426, filed on May 9, 2025, and Jun. 24, 2025, respectively, in the Korean Intellectual Property Office, the entire contents of which are hereby incorporated by reference.

### BACKGROUND

The present disclosure relates to a wiring substrate and a semiconductor package including the same, and in particular to a semiconductor package including an interposer substrate and a method of fabricating the same.

With the recent advance in the electronics industry, the demand for high-performance, high-speed, and compact electronic components are increasing. To meet this demand, packaging technologies of mounting a plurality of semiconductor chips in a single package are being developed.

Recently, the demand for portable electronic devices has been rapidly increasing in the market, and thus, it is necessary to reduce sizes and weights of electronic components constituting the portable electronic devices. To meet these demands, it is necessary to develop packaging technologies of reducing a size and a weight of each component and of integrating a plurality of individual components in a single package. As the number of stacked devices increases, various technical issues are occurring.

For example, in the case where the number of semiconductor chips in a semiconductor package increases, there are difficulties in placing multiple semiconductor chips in a printed circuit board. In order to alleviate these difficulties, a semiconductor package including an interposer, which is used to connect the semiconductor chips to each other, is being developed.

### SUMMARY

One or more embodiments of the present disclosure provides a wiring substrate with improved electrical characteristics and a semiconductor package including the same.

One or more embodiments of the present disclosure provides a wiring substrate with a high integration density and a semiconductor package including the same.

According to an aspect of the disclosure, a wiring substrate, including: a first redistribution layer; a first core layer; a second core layer; and a second redistribution layer, which are sequentially stacked; a first capacitor on a first surface of the first core layer; and a second capacitor on a first surface of the second core layer, in which the first core layer comprises a first via, which penetrates the first core layer and is connected to the first redistribution layer, in which the second core layer comprises a second via, which penetrates the second core layer and is connected to the second redistribution layer, in which the first via and the second via are in contact with each other between the first core layer and the second core layer, in which the first capacitor is in a first recess, which is in the first surface of the first core layer and is on one side of the first via, and the second capacitor is in a second recess, which is in the first surface of the second core layer and is on one side of the second via.

According to an aspect of the disclosure, a semiconductor package, includes: a substrate; a semiconductor chip disposed on the substrate; and a mold layer provided on the substrate to cover the semiconductor chip, in which the substrate includes: a first redistribution layer; a first core layer on the first redistribution layer, the first core layer comprising a first via penetrating the first core layer; a second core layer on the first core layer, the second core layer comprising a second via penetrating the second core layer; a second redistribution layer on the second core layer; a first capacitor between the first redistribution layer and the first core layer; and a second capacitor between the second redistribution layer and the second core layer, in which a width of the first via decreases as a distance from the first redistribution layer increases, in which a width of the second via decreases as a distance from the second redistribution layer increases, and in which, on a contact surface between the first via and the second via, the first via and the second via form a single object that comprises a same material.

According to an aspect of the disclosure, a semiconductor package includes: a package substrate; an interposer substrate on the package substrate; and a first semiconductor chip and a chip stack on the interposer substrate and spaced apart from each other in a first direction, in which the chip stack comprises second semiconductor chips which are stacked in a second direction, in which the interposer substrate comprises a first redistribution layer, a core structure, and a second redistribution layer which are sequentially stacked, in which the core structure includes: a first core layer, an interface layer, and a second core layer, which are sequentially stacked; a first via, which penetrates the first core layer and is coupled to the first redistribution layer; a second via, which penetrates the second core layer and is coupled to the second redistribution layer; a first capacitor, which is between the first core layer and the first redistribution layer and is spaced apart from the first via in the first direction; and a second capacitor, which is between the second core layer and the second redistribution layer and is spaced apart from the second via in the first direction, in which a contact surface between the first via and the second via is placed within the interface layer, in which, on the contact surface between the first via and the second via, a width of the first via is larger than a width of the second via.

### BRIEF DESCRIPTION OF DRAWINGS

FIG. 1 is a sectional view illustrating a wiring substrate according to one or more embodiments of the present disclosure.

FIG. 2 is an enlarged sectional view illustrating a portion ‘A’ of FIG. 1.

FIGS. 3-5 are sectional views illustrating capacitors of a wiring substrate according to embodiments of the present disclosure.

FIGS. 6-8 are enlarged sectional views illustrating the portion ‘A’ of FIG. 1.

FIG. 9 is a sectional view illustrating a wiring substrate according to one or more embodiments of the present disclosure.

FIG. 10 is an enlarged sectional view illustrating a portion ‘B’ of FIG. 9.

FIG. 11 is a sectional view illustrating a wiring substrate according to one or more embodiments of the present disclosure.

FIG. 12 is an enlarged sectional view illustrating a portion ‘C’ of FIG. 11.

FIG. 13 is a sectional view illustrating a wiring substrate according to one or more embodiments of the present disclosure.

FIG. 14 is an enlarged sectional view illustrating a portion ‘D’ of FIG. 13.

FIG. 15 is an enlarged sectional view illustrating a portion ‘E’ of FIG. 14.

FIG. 16 is an enlarged sectional view illustrating the portion ‘D’ of FIG. 13.

FIGS. 17 and 18 are sectional views illustrating semiconductor packages according to embodiments of the present disclosure.

FIGS. 19A-24A are sectional views illustrating a method of fabricating a wiring substrate according to one or more embodiments of the present disclosure.

FIGS. 19B-24B are enlarged sectional views illustrating portions ‘F’ of FIGS. 19A-24A.

### DETAILED DESCRIPTION

Example embodiments of the present disclosures will now be described more fully with reference to the accompanying drawings, in which example embodiments are shown.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10 % of Y. In one or more examples, when specifying that a parameter is about X, the term “about” may be understood as being within 10 % of X.

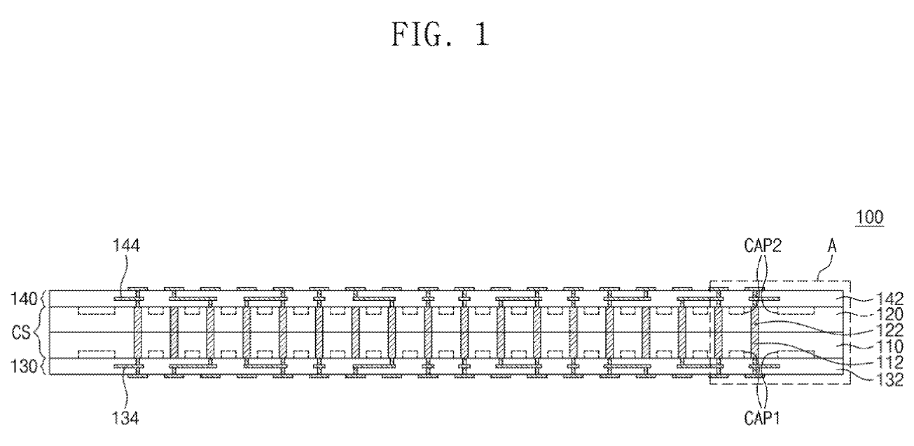

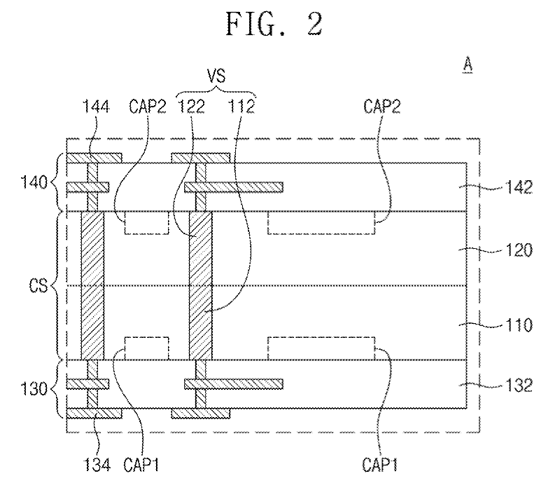

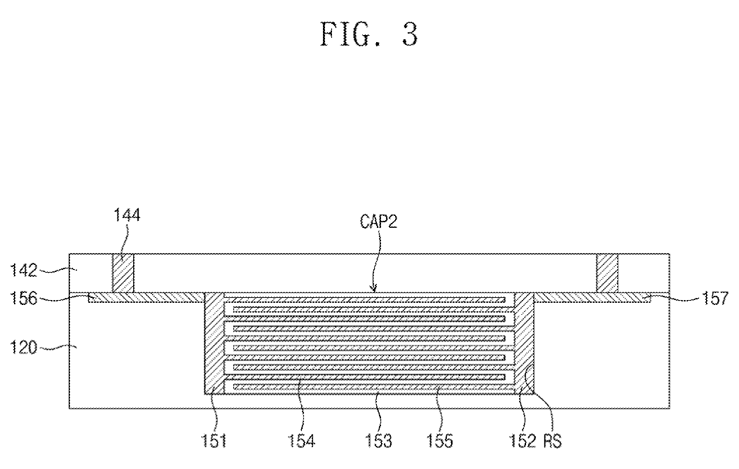

FIG. 1 is a sectional view illustrating a wiring substrate according to one or more embodiments of the present disclosure. FIG. 2 is an enlarged sectional view illustrating a portion ‘A’ of FIG. 1. FIGS. 3-5 are sectional views illustrating capacitors of a wiring substrate according to embodiments of the present disclosure.

Referring to FIGS. 1 and 2, a wiring substrate 100 according to one or more embodiments of the present disclosure may include a core structure CS, a first redistribution layer 130, and a second redistribution layer 140.

The core structure CS may include a first core layer 110, a second core layer 120, a first via 112, a second via 122, a first capacitor CAP1, and a second capacitor CAP2.

The first core layer 110 may have a plate-shaped structure. The first core layer 110 may have a first top surface and a first bottom surface, which are opposite to each other. The first top surface and the second bottom surface may be parallel to each other. The first top surface and the first bottom surface may be substantially flat surfaces. The first core layer 110 may include a semiconductor substrate. The first core layer 110 may be formed of or include a semiconductor material. For example, the semiconductor material may include silicon (Si). In one or more examples, the first core layer 110 may be formed of or include an insulating material. As an example, the insulating material may include an insulating polymer or glass.

The first via 112 may be provided in the first core layer 110 to penetrate the first core layer 110. The first via 112 may penetrate the first core layer 110 vertically and may be exposed to regions outside the first top and bottom surfaces of the first core layer 110. The first via 112 may have a vertically-extending pillar shape. The first via 112 may have a substantially constant width regardless of its position in a vertical direction. In one or more embodiments, a plurality of first vias 112 may be provided. The first vias 112 may be formed of or include a metal material (e.g., copper (Cu)).

The second core layer 120 may be disposed on the first core layer 110. The second core layer 120 may have a plate-shaped structure. The second core layer 120 may have a second top surface and a second bottom surface, which are opposite to each other. The second top surface and the second bottom surface may be parallel to each other. The second top surface and the second bottom surface may be substantially flat surfaces. The second bottom surface of the second core layer 120 may be in contact with the first top surface of the first core layer 110. There may be a visible contact surface between the first and second core layers 110 and 120. However, the present disclosure is not limited to this example. The second core layer 120 may include a semiconductor substrate. The second core layer 120 may include a semiconductor material. For example, the semiconductor material may include silicon (Si). In one or more examples, the second core layer 120 may be formed of or include an insulating material. As an example, the insulating material may include an insulating polymer or glass. The first and second core layers 110 and 120 may include the same material. However, the present disclosure is not limited to this example, and in one or more embodiments, the first and second core layers 110 and 120 may be formed of, or include, different materials from each other.

The second via 122 may be provided in the second core layer 120 to penetrate the second core layer 120. The second via 122 may penetrate the second core layer 120 vertically and may be exposed to regions outside the second top and bottom surfaces of the second core layer 120. The second via 122 may have a vertically-extending pillar shape. The second via 122 may have a substantially constant width regardless of its position in the vertical direction. In one or more embodiments, a plurality of second vias 122 may be provided. When viewed in a plan view, the arrangement of the second vias 122 may correspond to the arrangement of the first vias 112. For example, each of the second vias 122 may be aligned to a corresponding one of the first vias 112. The second vias 122 may be formed of or include a metal material (e.g., copper (Cu)).

The first vias 112 and the second vias 122 may be in contact with each other on a contact surface between the first and second core layers 110 and 120. Hereinafter, for brevity’s sake, the description will refer to one first via 112 and one second via 122 that are vertically aligned to each other. A contact surface between the first and second vias 112 and 122 may be placed at substantially the same vertical level as the contact surface between the first and second core layers 110 and 120. As an example, the contact surface between the first and second vias 112 and 122 may be coplanar with the contact surface between the first and second core layers 110 and 120. On the contact surface between the first and second vias 112 and 122, the width of the first via 112 may be substantially equal to the width of the second via 122. In one or more examples, the width of the first via 112 and the width of the second via 122 may be different from each other, on the contact surface between the first and second vias 112 and 122. On the contact surface between the first and second vias 112 and 122, the first and second vias 112 and 122 may form a single object that is formed of the same material. In one or more embodiments, the first and second vias 112 and 122 may form an intermetal hybrid bonding structure. In the present specification, the hybrid bonding structure may mean a bonding structure which is formed by two materials, which are of the same kind and are fused at an interface therebetween, or by the interfacial fusion between a first constituent containing a first material and a second constituent containing a second material which is a compound of the first material. For example, the first and second vias 112 and 122 may be in direct contact with each other and may have a continuous structure, forming no visible interface between the first and second vias 112 and 122. For convenience in description, a pair of first and second vias 112 and 122, which are vertically connected to each other, will be referred to as a via structure VS. In other words, a plurality of via structures VS may be provided to vertically penetrate the first and second core layers 110 and 120, and each of the via structures VS may include one first via 112 and one second via 122, which are vertically connected to each other. In one or more examples, each of the first vias 112 and second vias 112 may have a same width and/or length. In one or more examples, at least one first via 112 may have a different width and/or length than at least one second via 122. In one or more examples, each of the first vias 112 and second vias 122 may be spaced apart by a same distance. In one or more examples, at least one first via 112 and at least one second via 122 that contact each other may be spaced apart from other first and second vias by a different distance.

The first redistribution layer 130 may be disposed on the first bottom surface of the first core layer 110. The first redistribution layer 130 may cover the first bottom surface of the first core layer 110. The first redistribution layer 130 may include a first insulating pattern 132 and first wiring patterns 134.

The first insulating pattern 132 may cover the first bottom surface of the first core layer 110. The first insulating pattern 132 may include a photoimageable dielectric (PID) material. For example, the PID materials may include at least one of photoimageable polyimide (PI), polybenzoxazole (PBO), phenol-based polymers, or benzocyclobutene-based polymers. In one or more examples, the first insulating pattern 132 may include an insulating material. For example, the first insulating pattern 132 may be formed of or include at least one of silicon oxide (SiO), silicon nitride (SiN), silicon oxynitride (SiON), silicon carbonitride (SiCN), or insulating polymers. FIG. 1 illustrates an example, in which the first insulating pattern 132 is provided as a single layer, but the present disclosure is not limited to this example. The first insulating pattern 132 may be provided to have a multi-layered structure, in which a plurality of insulating layers are stacked.

The first wiring patterns 134 may be provided in the first insulating pattern 132. The first wiring patterns 134 may be horizontally extended within the first insulating pattern 132. The first wiring patterns 134 may be elements for redistribution of the first redistribution layer 130. The first wiring patterns 134 may include a conductive material. For example, the first wiring patterns 134 may be formed of or include copper (Cu) or aluminum (Al).

The first wiring patterns 134 may have a damascene structure. For example, the first wiring patterns 134 may include a head portion and a tail portion, which are connected to form a single object. The head and tail portions of the first wiring patterns 134 may have a section in the shape of an inverted ‘T’.

The head portions of the first wiring patterns 134 may be wiring portions horizontally extending wiring patterns in the first redistribution layer 130. The head portion may be horizontally extended within the first insulating pattern 132.

The tail portions of the first wiring patterns 134 may be via portions, which are used to vertically connect the wiring patterns in the first redistribution layer 130 to each other. The tail portion may be coupled to the head portions of the first wiring patterns 134 placed thereon or thereunder. The tail portions of the uppermost ones of the first wiring patterns 134 may penetrate the first insulating pattern 132 and may be exposed to a region on the top surface of the first redistribution layer 130 (i.e., the top surface of the first redistribution layer 130). The tail portions of the uppermost ones of the first wiring patterns 134 may be coupled to bottom surfaces of the first vias 112.

The second redistribution layer 140 may be disposed on the second top surface of the second core layer 120. The second redistribution layer 140 may cover the second top surface of the second core layer 120. The second redistribution layer 140 may include a second insulating pattern 142 and second wiring patterns 144.

The second insulating pattern 142 may cover the second top surface of the second core layer 120. The second insulating pattern 142 may include at least one of PID materials. For example, the PID materials may include at least one of photoimageable polyimide (PI), polybenzoxazole (PBO), phenol-based polymers, or benzocyclobutene-based polymers. In one or more examples, the second insulating pattern 142 may include an insulating material. For example, the second insulating pattern 142 may include at least one of silicon oxide (SiO), silicon nitride (SiN), silicon oxynitride (SiON), silicon carbonitride (SiCN), or insulating polymers. FIG. 1 illustrates an example, in which the second insulating pattern 142 is provided as a single layer, but the present disclosure is not limited to this example. The second insulating pattern 142 may be provided to have a multi-layered structure, in which a plurality of insulating layers are stacked.

The second wiring patterns 144 may be provided in the second insulating pattern 142. The second wiring patterns 144 may be horizontally extended within the second insulating pattern 142. The second wiring patterns 144 may be elements for redistribution of the second redistribution layer 140. The second wiring patterns 144 may include a conductive material. For example, the second wiring patterns 144 may be formed of or include copper (Cu) or aluminum (Al).

The second wiring patterns 144 may have a damascene structure. For example, the second wiring patterns 144 may include a head portion and a tail portion, which are connected to form a single object. The head and tail portions of the second wiring patterns 144 may have a section in the shape of ‘T’.

The head portions of the second wiring patterns 144 may be wiring portions horizontally extending wiring patterns in the second redistribution layer 140. The head portion may be horizontally extended within the second insulating pattern 142.

The tail portions of the second wiring patterns 144 may be via portions, which are used to vertically connect the wiring patterns in the second redistribution layer 140 to each other. The tail portion may be coupled to the head portion of the second wiring pattern 144 placed thereon or thereunder. The tail portion of the lowermost one of the second wiring patterns 144 may penetrate the second insulating pattern 142 and may be exposed to a region on the bottom surface of the second redistribution layer 140 (i.e., the bottom surface of the second redistribution layer 140). The tail portion of the lowermost second wiring pattern 144 may be coupled to the top surface of the second via 122.

The first wiring patterns 134 of the first redistribution layer 130 may be electrically connected to the second wiring patterns 144 of the second redistribution layer 140 through the first vias 112 and the second vias 122.

In one or more embodiments, each of the via structures VS, which are used to electrically connect the first redistribution layer 130 to the second redistribution layer 140, may include the first and second vias 112 and 122 that are vertically bonded to each other. Accordingly, the via structures VS may have a reduced largest width and an increased aspect ratio. In one or more examples, the large aspect ratio of the via structures VS may indicate that their vertical length is larger than their horizontal width. In this case, the via structures VS may be spaced apart from each other with a small horizontal distance, and the integration density of the via structures VS in the wiring substrate 100 may be increased. That is, it may be possible to provide a wiring substrate with improved electrical characteristics and an increased integration density. This will be described in more detail with reference to a fabrication method to be described below.

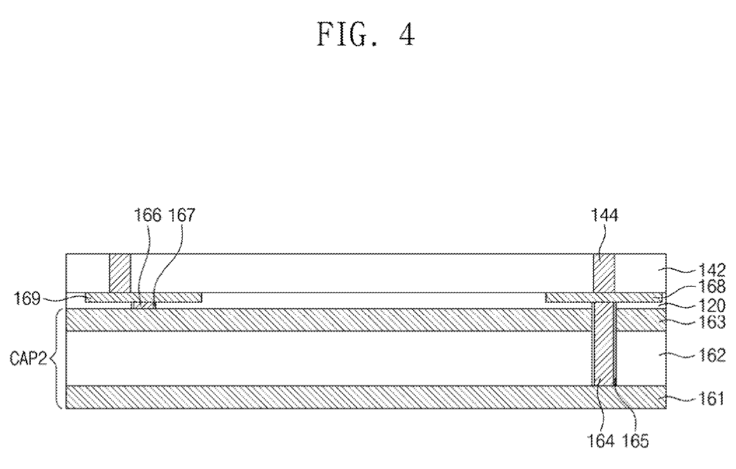

Referring to FIGS. 1 and 2, the first capacitor CAP1 may be disposed between the first redistribution layer 130 and the first core layer 110. In one or more examples,, the first capacitor CAP1 may be provided in a lower portion of the first core layer 110. The first capacitor CAP1 may be exposed to the outside through the first bottom surface of the first core layer 110. As an example, the first capacitor CAP1 may be provided in a first recess, which is formed through the first bottom surface of the first core layer 110. The structure of the first capacitor CAP1 will be described in more detail with reference to FIGS. 3 and 4. The first wiring patterns 134 of the first redistribution layer 130 may be provided to penetrate the first insulating pattern 132 and may be connected to the first capacitor CAP1. In one or more embodiments, a plurality of first capacitors CAP1 may be provided. The first capacitors CAP1 may be placed near or between the first vias 112.

In one or more embodiments, the first vias 112 may have a small width, and in this case, it may be possible to reduce an occupying area of the first vias 112 in the first core layer 110. Accordingly, it may be possible to increase the number of the first capacitors CAP1 that can be placed in the first core layer 110 and to improve the electrical characteristics of the wiring substrate.

The second capacitor CAP2 may be disposed between the second redistribution layer 140 and the second core layer 120. In one or more examples,, the second capacitor CAP2 may be provided in an upper portion of the second core layer 120. The second capacitor CAP2 may be exposed to a region on the second top surface of the second core layer 120. As an example, the second capacitor CAP2 may be provided in a second recess, which is formed through the second top surface of the second core layer 120. The structure of the second capacitor CAP2 will be described in more detail with reference to FIGS. 3 and 4. The second wiring patterns 144 of the second redistribution layer 140 may be provided to penetrate the second insulating pattern 142 and may be connected to the second capacitor CAP2. In one or more embodiments, a plurality of second capacitors CAP2 may be provided. The second capacitors CAP2 may be placed near or between the second vias 122.

In one or more embodiments, the second vias 122 may have a reduced width and may have a reduced occupying area in the second core layer 120. Thus, it may be possible to increase the number of the second capacitors CAP2, which can be placed in the second core layer 120, and/or to improve the electrical characteristics of the wiring substrate.

In one or more embodiments, the first capacitors CAP1 may be provided near a bottom surface of the core structure CS, and the second capacitors CAP2 may be provided near a top surface of the core structure CS. Since the capacitors are provided near two surfaces of the core structure CS, it may be possible to increase the number of the capacitors that can be placed in the wiring substrate 100 and to improve the electrical characteristics of the wiring substrate 100. In one or more examples, a first capacitor CAP1 provided near a bottom surface of the core structure CS may refer to a capacitor that is within a predetermined distance of the bottom surface of the core structure CS or closer to the bottom surface of the core structure CS than a top surface of the core structure CS. In one or more examples, a second capacitor CAP2 provided near a top surface of the core structure CS may refer to a capacitor that is within a predetermined distance of the top surface of the core structure CS or closer to the top surface of the core structure CS than a bottom surface of the core structure CS.

Hereinafter, the structure of the first and second capacitors CAP1 and CAP2 will be described in more detail, but for brevity’s sake, the description will refer to one of the second capacitor CAP2 as an example.

Referring to FIG. 3, the second capacitor CAP2 may be a capacitor, which is provided in a first recess RS formed in the second top surface of the second core layer 120. The first recess RS may be formed in the second core layer 120. The first recess RS may have a shape that is recessed from the second top surface of the second core layer 120 into the second core layer 120. The second capacitor CAP2 may include a first electrode 151 and a second electrode 152, which are horizontally spaced apart from each other in the first recess RS, and a dielectric material 153, which is provided to fill a space between the first and second electrodes 151 and 152.

The first and second electrodes 151 and 152 may be connected to first and second capacitor pads 156 and 157, respectively, which are provided in the second top surface of the second core layer 120. The first and second capacitor pads 156 and 157 may be wiring patterns or pads, which are formed in the second top surface of the second core layer 120. In one or more examples, the first and second capacitor pads 156 and 157 may be portions of the second wiring patterns 144 of the second redistribution layer 140. Each of the first and second capacitor pads 156 and 157 may be extended from the second top surface of the second core layer 120 toward the first recess RS and may be in contact with the first electrode 151 or the second electrode 152.

To increase the electrostatic capacitance of the second capacitor CAP2, the second capacitor CAP2 may further include first sub-electrodes 154 and second sub-electrodes 155, which are alternately provided between the first and second electrodes 151 and 152. The first sub-electrodes 154 may be connected to the first electrode 151, and the second sub-electrodes 155 may be connected to the second electrode 152.

One or more of the second wiring patterns 144 of the second redistribution layer 140 may penetrate the second insulating pattern 142 and may be coupled to the first capacitor pad 156 or the second capacitor pad 157.

In one or more embodiments, the second capacitor CAP2 may be a metal-insulator-metal (MIM) capacitor. FIG. 4 is a sectional view illustrating another example of the second capacitor CAP2, and as shown in FIG. 4, the second capacitor CAP2 may be a capacitor, which is provided in a first recess formed in the second top surface of the second core layer 120. The second capacitor CAP2 may include a first electrode 161 and a second electrode 163, which are vertically spaced apart from each other, and a dielectric material 162, which fills a space between the first electrode 161 and the second electrode 163.

The first electrode 161 may be electrically connected to the first capacitor pad 168 through a first penetration via 164 provided between a first capacitor pad 168 and the first electrode 161. The first penetration via 164 may be extended from the bottom surface of the first capacitor pad 168 to penetrate the second electrode 163 and the dielectric material 162 and may be coupled to the top surface of the first electrode 161. The second electrode 163 may be electrically connected to the second capacitor pad 169 through a second penetration via 166 provided between a second capacitor pad 169 and the second electrode 163. The second penetration via 166 may be extended from the bottom surface of the second capacitor pad 169 and may be coupled to the top surface of the second electrode 163. The first penetration via 164 and the second penetration via 166 may include a conductive material. The first penetration via 164 and the second penetration via 166 may include insulating layers 165 and 167 which are provided to enclose outer surfaces thereof.

At least one of the second wiring patterns 144 of the second redistribution layer 140 may penetrate the second insulating pattern 142 and may be coupled to the first capacitor pad 168 or the second capacitor pad 169.

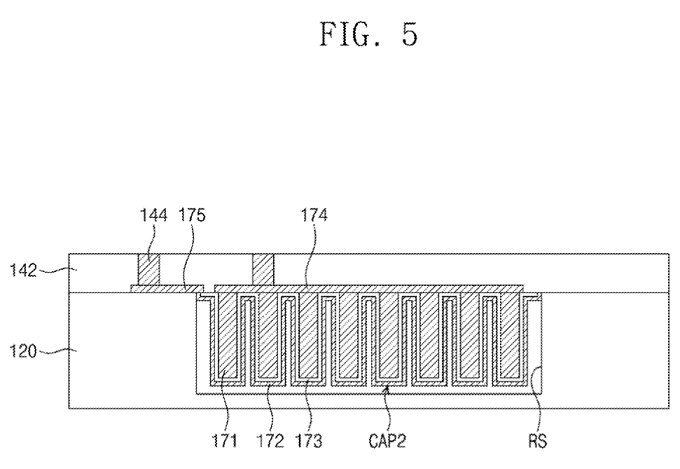

In one or more embodiments, the second capacitor CAP2 may be a deep trench capacitor (DTC). FIG. 5 is a sectional view illustrating an example of the second capacitor CAP2, and as shown in FIG. 5, the second capacitor CAP2 may be a capacitor that is provided in the first recess RS formed through the second top surface of the second core layer 120. The second capacitor CAP2 may include a first electrode 171, which is extended in a vertical direction, and a dielectric material 173 and a second electrode 172, which are sequentially provided to cover the first electrode 171 conformally.

The first electrode 171 in the first recess RS may have a vertically-extending pillar shape. In one or more embodiments, a plurality of first electrodes 171 may be provided in the first recess RS. The first electrodes 171 may have a uniform width and a uniform height. The first electrodes 171 may have top surfaces that are located at substantially the same vertical level. The first electrodes 171 may be horizontally spaced apart from each other. When viewed in a plan view, the first electrodes 171 may be arranged in various shapes. For example, the first electrodes 171 may be arranged in a zigzag or honeycomb shape. Since the first electrodes 171 are arranged in the zigzag or honeycomb shape, it may be possible to effectively increase the diameter or integration density of the first electrodes 171. The dielectric material 173 and the second electrode 172 may be sequentially disposed on the first electrodes 171. The dielectric material 173 and the second electrode 172 may conformally cover the bottom and side surfaces of the first electrodes 171.

The dielectric material 173 may be placed between the first electrodes 171 and the second electrode 172. The dielectric material 173 may cover the first electrodes 171 with a uniform thickness and may fill a space between the first electrodes 171 and the second electrode 172. The dielectric material 173 may cover the bottom and side surfaces of the first electrodes 171. The dielectric material 173 may be thinner than the first electrodes 171. The dielectric material 173 may be formed of or include at least one of metal oxides (e.g., HfO₂, ZrO₂, Al₂O₃, La₂O₃, Ta₂O₃, and TiO₂) or perovskite piezoelectric materials (e.g., SrTiO₃, (Ba,Sr)TiO₃, BaTiO₃, PZT, and PLZT) and may be provided in a single- or multi-layered structure.

The second electrode 172 may be located on the dielectric material 173. The second electrode 172 may conformally over the dielectric material 173. In one or more examples, the second electrode 172 may be provided on the dielectric material 173 to fill a space between the first electrodes 171. In the case where a plurality of first electrodes 171 are provided, a single second electrode 172 may be provided to cover the first electrodes 171. In other words, the first electrodes 171 may share the single second electrode 172. The first electrodes 171 and the second electrode 172 may be formed of, or include, at least one of high melting point metals (e.g., cobalt, titanium, nickel, tungsten, and molybdenum) and/or metal nitrides (e.g., titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), and tungsten nitride (WN)).

The first electrodes 171 and the second electrode 172 may be connected to first and second capacitor pads 174 and 175, respectively, which are provided on the second top surface of the second core layer 120. The first and second capacitor pads 174 and 175 may be wiring patterns or pads, which are formed on the second top surface of the second core layer 120. In one or more examples, the first and second capacitor pads 174 and 175 may be portions of the second wiring pattern 144 of the second redistribution layer 140. Each of the first and second capacitor pads 174 and 175 may be extended from a region on the second top surface of the second core layer 120 toward a region on the first recess RS and may be in contact with the first electrodes 171 and the second electrode 172. In one or more examples, the first capacitor pad 174 may be located on the first recess RS. As an example, the first capacitor pad 174 may be located on the first electrodes 171. The first electrodes 171 may be coupled to the bottom surface of the first capacitor pad 174.

At least one of the second wiring patterns 144 of the second redistribution layer 140 may be provided to penetrate the second insulating pattern 142 and may be coupled to the first capacitor pad 174 or the second capacitor pad 175.

So far, one example of the second capacitor CAP2 has been described, but the present disclosure is not limited to this example. In one or more embodiments, the second capacitor CAP2 may include at least one of various capacitor devices. In one or more examples, a passive device (e.g., a resistor device or an inductor device) may be provided in place of the second capacitor CAP2.

The first capacitor CAP1 may be provided to have a structure that is the same as or similar to the second capacitor CAP2. For example, the first capacitor CAP1 may be provided in the second recess formed on the first bottom surface of the first core layer 110. In one or more embodiments, the first capacitor CAP1 may include a capacitor including first and second sub-electrodes, which are alternately stacked on top of each other, an MIM capacitor including vertically-separated electrodes, or a DTC including a pillar-shaped first electrodes and a second electrode conformally covering the same.

In the following embodiments, for convenience of description, detailed explanations of technical features that overlap with those described earlier with reference to FIGS. 1-5 will be omitted, and only the differences will be described in detail. For elements identical to those of the semiconductor device according to one or more embodiments of the present disclosure described above, the same reference numerals may be used.

FIG. 6 is an enlarged sectional view illustrating the portion ‘A’ of FIG. 1.

Referring to FIGS. 1 and 6, the first via 112 may be disposed in the first core layer 110 to penetrate the first core layer 110. The first via 112 may penetrate the first core layer 110 vertically and may be exposed to regions outside the first top and bottom surfaces of the first core layer 110. The first via 112 may be vertically extended. A width of the first via 112 may decrease as a distance from the first bottom surface of the first core layer 110 increases in a direction toward the first top surface.

The second via 122 may be provided in the second core layer 120 to penetrate the second core layer 120. The second via 122 may penetrate the second core layer 120 vertically and may be exposed to regions outside the second top and bottom surfaces of the second core layer 120. The second via 122 may be vertically extended. A width of the second via 122 may decrease as a distance from the second top surface of the second core layer 120 increases in a direction toward the second bottom surface.

When measured on the contact surface between the first and second vias 112 and 122, the width of the first via 112 and the width of the second via 122 may be substantially equal to each other.

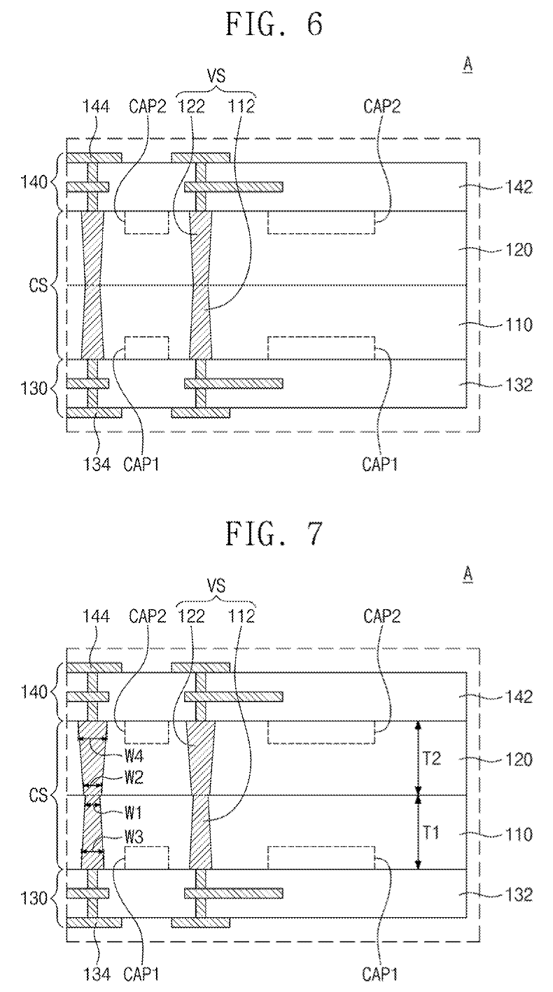

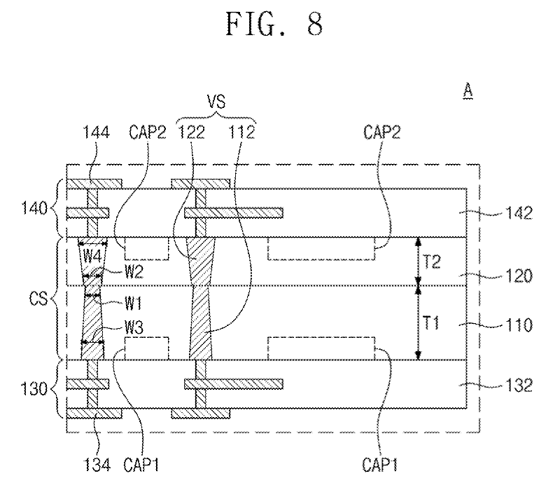

In one or more examples, when measured at the level of the contact surface between the first and second vias 112 and 122, the width of the first via 112 and the width of the second via 122 may be different from each other. Hereinafter, embodiments, in which the first and second vias 112 and 122 have different widths from each other, will be described in more detail with reference to FIGS. 7 and 8.

FIG. 7 is an enlarged sectional view illustrating the portion ‘A’ of FIG. 1.

Referring to FIG. 7, when measured on the contact surface between the first and second vias 112 and 122, a first width W1 of the first via 112 may be smaller than a second width W2 of the second via 122. A third width W3 of the first via 112 on the first bottom surface of the first core layer 110 may be smaller than a fourth width W4 of the second via 122 on the second top surface of the second core layer 120. A first thickness T1 of the first core layer 110 may be substantially equal to a second thickness T2 of the second core layer 120.

FIG. 8 is an enlarged sectional view illustrating the portion ‘A’ of FIG. 1.

Referring to FIG. 8, on the contact surface between the first and second vias 112 and 122, the first width W1 of the first via 112 may be smaller than the second width W2 of the second via 122. The third width W3 of the first via 112 on the first bottom surface of the first core layer 110 may be substantially equal to the fourth width W4 of the second via 122 on the second top surface of the second core layer 120. The first thickness T1 of the first core layer 110 may be larger than the second thickness T2 of the second core layer 120.

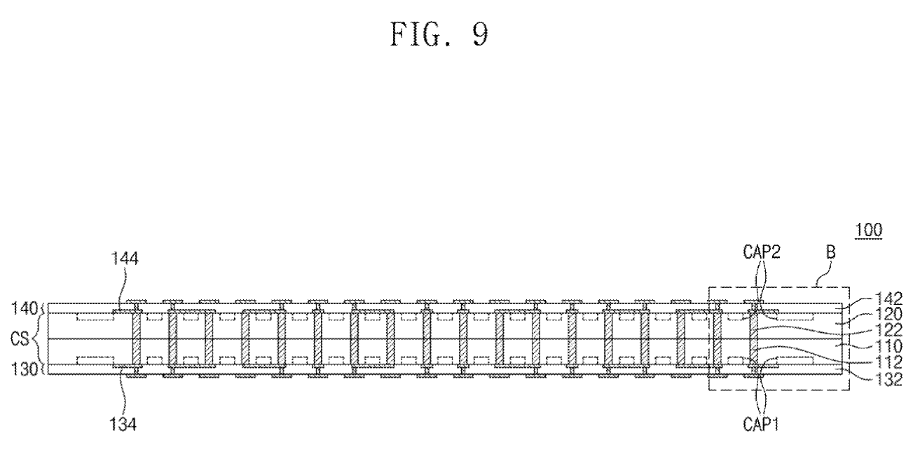

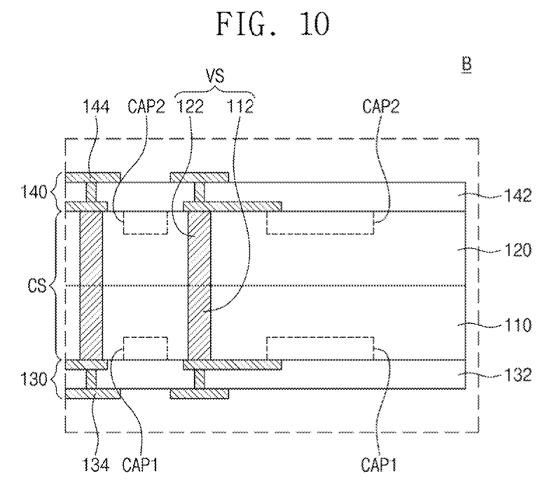

FIG. 9 is a sectional view illustrating a wiring substrate according to one or more embodiments of the present disclosure. FIG. 10 is an enlarged sectional view illustrating a portion ‘B’ of FIG. 9.

Referring to FIGS. 9 and 10, the first redistribution layer 130 may be disposed on the first bottom surface of the first core layer 110. The first redistribution layer 130 may include the first insulating pattern 132 and the first wiring patterns 134. The first wiring patterns 134 may include a head portion and a tail portion, which are connected to form a single object. The uppermost one of the first wiring patterns 134 may not have the tail portion, and the first via 112 may be coupled to a top surface of the head portion.

The second redistribution layer 140 may be disposed on the second top surface of the second core layer 120. The second redistribution layer 140 may include the second insulating pattern 142 and the second wiring patterns 144. The second wiring patterns 144 may include a head portion and a tail portion, which are connected to form a single object. The lowermost one of the second wiring patterns 144 may not have the tail portion, and the second via 122 may be coupled to a bottom surface of the head portion.

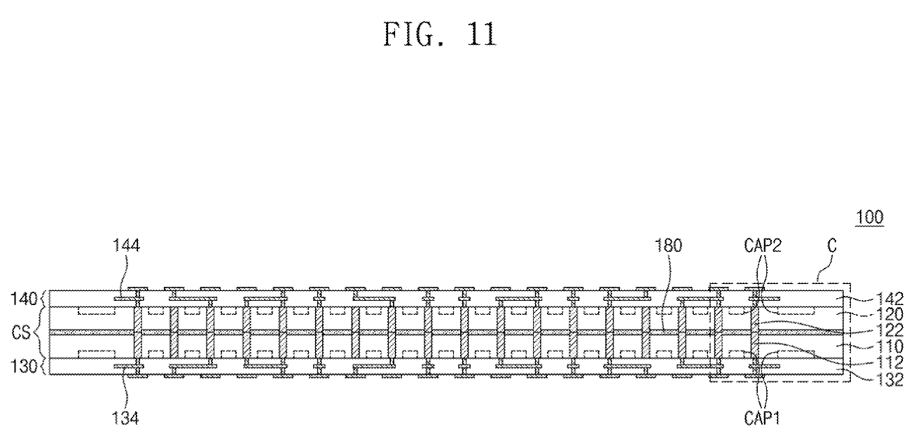

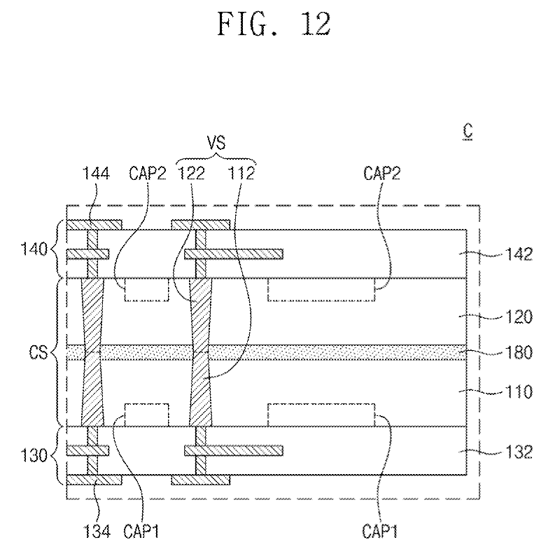

FIG. 11 is a sectional view illustrating a wiring substrate according to one or more embodiments of the present disclosure. FIG. 12 is an enlarged sectional view illustrating a portion ‘C’ of FIG. 11.

Referring to FIGS. 11 and 12, the core structure CS may further include an interface layer 180 interposed between the first and second core layers 110 and 120.

The interface layer 180 may be in contact with the first top surface of the first core layer 110 and the second bottom surface of the second core layer 120. The interface layer 180 may include an insulating material. The interface layer 180 may include an oxide, nitride, or oxynitride material, in which an element constituting the first core layer 110 is contained. In one or more examples, the interface layer 180 may include an oxide, nitride, or oxynitride material, in which an element constituting the second core layer 120 is contained. In one or more embodiments, the interface layer 180 may be formed of or include at least one of silicon oxide (SiO), silicon nitride (SiN), or silicon oxynitride (SiON).

The via structure VS may be provided to penetrate the interface layer 180. For example, the first via 112 may be provided to penetrate at least a portion of the interface layer 180. The second via 122 may be provided to penetrate at least a portion of the interface layer 180. The first and second vias 112 and 122 may be in contact with each other within the interface layer 180. The contact surface between the first and second vias 112 and 122 may be located within the interface layer 180. The contact surface between the first and second vias 112 and 122 may be positioned between the top and bottom surfaces of the interface layer 180.

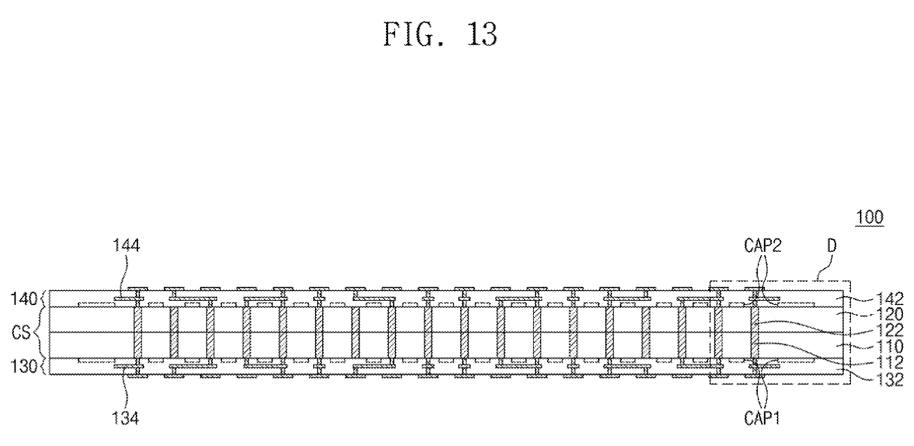

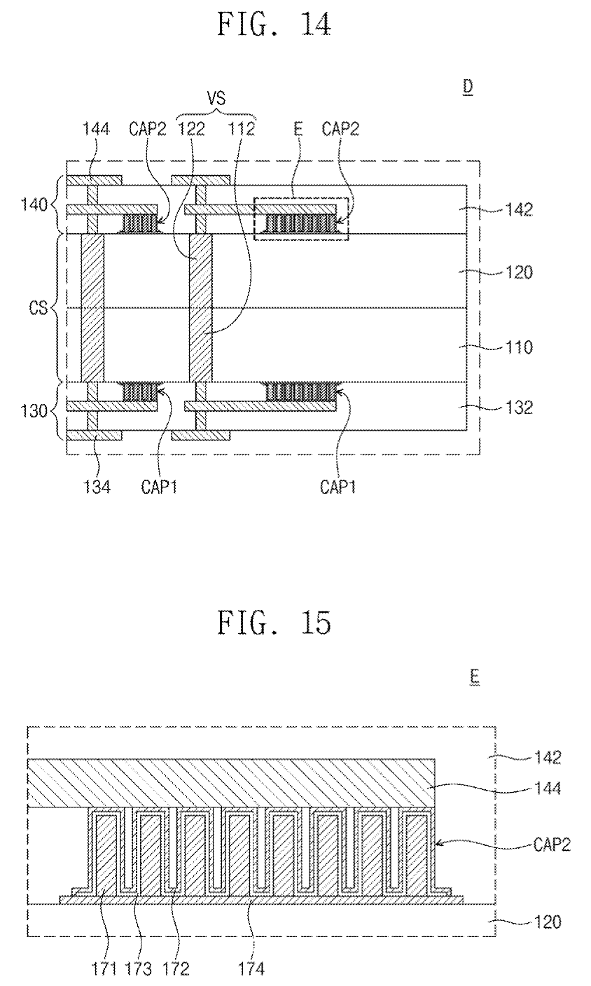

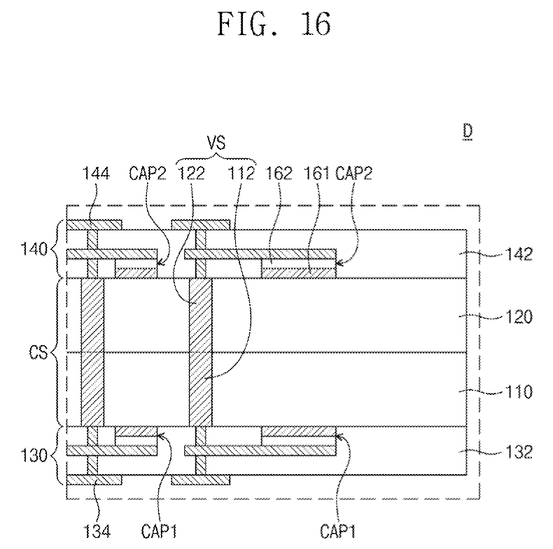

FIG. 13 is a sectional view illustrating a wiring substrate according to one or more embodiments of the present disclosure. FIG. 14 is an enlarged sectional view illustrating a portion ‘D’ of FIG. 13. FIG. 15 is an enlarged sectional view illustrating a portion ‘E’ of FIG. 14. FIG. 16 is an enlarged sectional view illustrating the portion ‘D’ of FIG. 13.

FIGS. 1-12 illustrate an example, in which the first capacitor CAP1 and the second capacitor CAP2 are provided in respective recesses formed in the first core layer 110 and the second core layer 120, but the present disclosure is not limited to these configurations.

Referring to FIG. 13, the first capacitor CAP1 may be disposed between the first redistribution layer 130 and the first core layer 110. In one or more examples,, the first capacitor CAP1 may be disposed in an upper portion of the first redistribution layer 130. In one or more examples, the first capacitor CAP1 may be disposed on the first bottom surface of the first core layer 110, and the first redistribution layer 130 may be disposed on the first bottom surface of the first core layer 110 to cover the first capacitor CAP1. However, the present disclosure is not limited to this example, and in one or more embodiments, the first capacitor CAP1 may be disposed in the first redistribution layer 130.

The second capacitor CAP2 may be disposed between the second redistribution layer 140 and the second core layer 120. In one or more examples,, the second capacitor CAP2 may be disposed in a lower portion of the second redistribution layer 140. In other words, the second capacitor CAP2 may be disposed on the second top surface of the second core layer 120, and the second redistribution layer 140 on the second top surface of the second core layer 120 may cover the second capacitor CAP2. However, the present disclosure is not limited to this example, and in one or more embodiments, the second capacitor CAP2 may be disposed in the second redistribution layer 140.

Hereinafter, the structure of the first and second capacitors CAP1 and CAP2 will be described in more detail, but for brevity’s sake, the description will refer to one of the second capacitor CAP2 as an example.

Referring to FIGS. 14 and 15, the second capacitor CAP2 may include the first electrode 171, which is extended in a vertical direction, and the dielectric material 173 and the second electrode 172, which are sequentially provided to cover the first electrode 171 conformally.

The first electrode 171 may have a vertically-extending pillar shape. In one or more embodiments, a plurality of first electrodes 171 may be provided. The first electrodes 171 may have a uniform width and a uniform height. The first electrodes 171 may be horizontally spaced apart from each other. When viewed in a plan view, the first electrodes 171 may be arranged in various shapes. For example, the first electrodes 171 may be arranged in a zigzag or honeycomb shape. The dielectric material 173 and the second electrode 172 may be sequentially disposed on the first electrodes 171. The dielectric material 173 and the second electrode 172 may conformally cover top and side surfaces of the first electrodes 171.

The dielectric material 173 may be placed between the first electrodes 171 and the second electrode 172. The dielectric material 173 may be formed to cover the first electrodes 171 with a uniform thickness and to fill a space between the first electrodes 171 and the second electrode 172. The dielectric material 173 may cover the top and side surfaces of the first electrodes 171. The dielectric material 173 may be thinner than the first electrodes 171.

The second electrode 172 may be located on the dielectric material 173. The second electrode 172 may conformally over the dielectric material 173. In one or more examples, the second electrode 172 may be provided on the dielectric material 173 to fill a space between the first electrodes 171. In the case where a plurality of first electrodes 171 are provided, a single second electrode 172 may be provided to cover the first electrodes 171. In other words, the first electrodes 171 may share the single second electrode 172.

The first electrodes 171 may be connected to the first capacitor pad 174 provided on the second top surface of the second core layer 120. The first capacitor pad 174 may be wiring patterns or pads, which are formed on the second top surface of the second core layer 120. In one or more examples, the first capacitor pad 174 may be a portion of the second wiring pattern 144 of the second redistribution layer 140. The second electrode 172 may be connected to a portion of the second wiring pattern 144 of the second redistribution layer 140. Unlike the illustrated structure, the second capacitor CAP2 may be provided in an capsized shape between the first capacitor pad 174 and the second wiring pattern 144. For example, the second electrode 172 may be connected to the first capacitor pad 174 provided on the second top surface of the second core layer 120, and the first electrodes 171 may be connected to a portion of the second wiring pattern 144 of the second redistribution layer 140.

In one or more embodiments, the second capacitor CAP2 may be a metal-insulator-metal (MIM) capacitor. FIG. 16 is a sectional view illustrating another example of the second capacitor CAP2, and as shown in FIG. 16, the second capacitor CAP2 may be a capacitor formed on the second top surface of the second core layer 120.

The second capacitor CAP2 may include the first electrode 161 and the dielectric material 162. The first electrode 161 may be vertically spaced apart from a portion of the second wiring pattern 144 of the second redistribution layer 140 with the dielectric material 162 interposed therebetween. The portion of the second wiring pattern 144 of the second redistribution layer 140, the dielectric material 162, and the first electrode 161 may constitute the second capacitor CAP2. In one or more examples, the portion of the second wiring pattern 144 of the second redistribution layer 140 may serve as an electrode of the second capacitor CAP2.

So far, one example of the second capacitor CAP2 has been described, but the present disclosure is not limited to this example. In one or more embodiments, the second capacitor CAP2 may include at least one of various capacitor devices. In one or more examples, a passive device (e.g., a resistor device or an inductor device) may be provided in place of the second capacitor CAP2.

The first capacitor CAP1 may be provided to have a structure that is the same as or similar to the second capacitor CAP2. For example, the first capacitor CAP1 may be provided on the first bottom surface of the first core layer 110. In one or more embodiments, the first capacitor CAP1 may include an MIM capacitor, in which the first wiring pattern 134 of the first redistribution layer 130 is spaced apart from an electrode, or a DTC including a pillar-shaped first electrodes and a second electrode conformally covering the same.

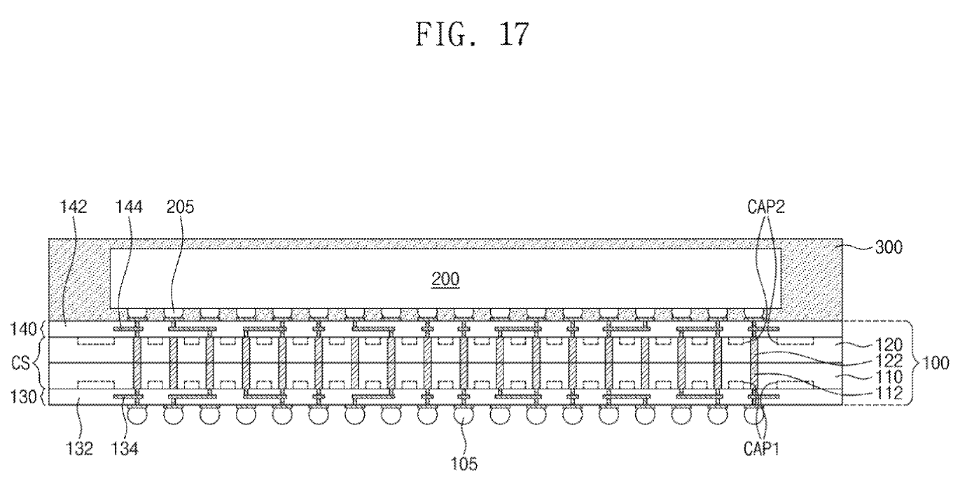

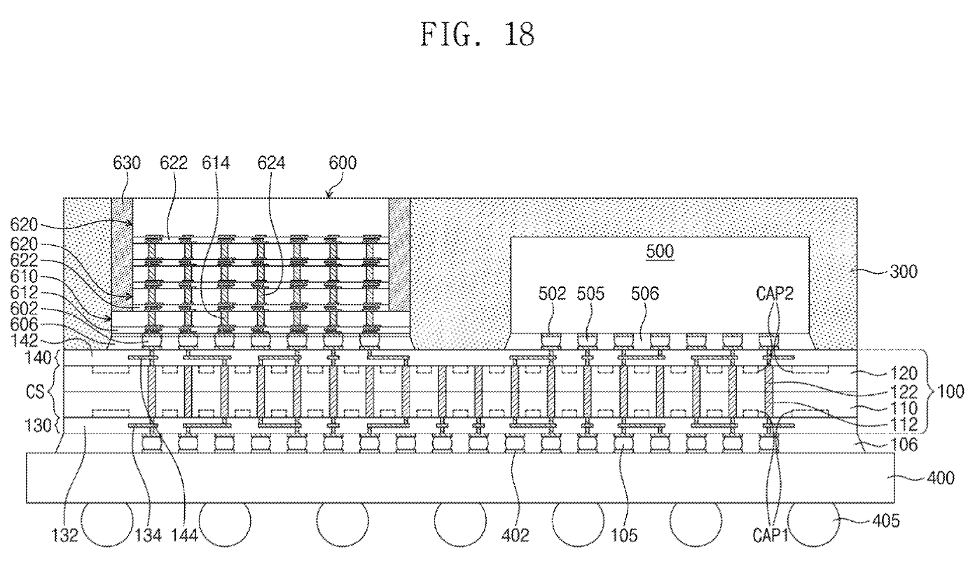

FIG. 17 is a sectional view illustrating a semiconductor package according to one or more embodiments of the present disclosure.

Referring to FIG. 17, the wiring substrate 100 may be provided. The wiring substrate 100 may be substantially the same as or similar to the wiring substrate described with reference to FIGS. 1-16.

One or more of the first wiring patterns 134, which are exposed to a region on a bottom surface of the first redistribution layer 130 of the wiring substrate 100, may correspond to lower pads of the wiring substrate 100. In one or more examples, the wiring substrate 100 may further include additional lower pads, which are provided on the bottom surface of the first redistribution layer 130 and are connected to the first wiring patterns 134. One or more of the second wiring patterns 144, which are exposed to a region on a top surface of the second redistribution layer 140 of the wiring substrate 100, may correspond to upper pads of the wiring substrate 100. In one or more examples, the wiring substrate 100 may further include additional upper pads, which are provided on the top surface of the second redistribution layer 140 and are connected to the second wiring patterns 144.

Substrate connection terminals 105 may be disposed below the wiring substrate 100. The substrate connection terminals 105 may be provided on the lower pads of the wiring substrate 100. The substrate connection terminals 105 may include solder balls or solder bumps, and the semiconductor package may be classified into a ball grid array (BGA), fine ball-grid array (FBGA), or land grid array (LGA), depending on the type and arrangement of the substrate connection terminals 105.

A semiconductor chip 200 may be disposed on the wiring substrate 100. The semiconductor chip 200 may be disposed on a top surface of the wiring substrate 100. The bottom surface of the semiconductor chip 200 may be an active surface, and the top surface of the semiconductor chip 200 may be an inactive surface. In one or more examples, the semiconductor chip 200 may be placed on the wiring substrate 100 in a face down manner. The semiconductor chip 200 may be a memory chip. In one or more examples, the semiconductor chip 200 may be a logic chip.

The semiconductor chip 200 may be mounted on the wiring substrate 100 in a flip chip manner. For example, the semiconductor chip 200 may be mounted on the wiring substrate 100 using chip terminals 205. The chip terminals 205 may be connection terminals, which are used to connect the semiconductor chip 200 to the wiring substrate 100. The chip terminals 205 may connect the chip pads of the semiconductor chip 200 to the upper pads of the wiring substrate 100. The chip terminals 205 may include solder balls or solder bumps. In one or more examples, the semiconductor chip 200 may be mounted on the wiring substrate 100 in a wire bonding manner. For example, the semiconductor chip 200 may be disposed on the wiring substrate 100 in a face up manner. The semiconductor chip 200 may include chip pads provided on the top surface thereof. Bonding wires may be extended from the chip pads to the upper pads of the wiring substrate 100.

A mold layer 300 may be provided on the wiring substrate 100. The mold layer 300 may cover the top surface of the wiring substrate 100. The mold layer 300 may be provided to enclose the semiconductor chip 200. The top surface of the mold layer 300 may cover the top surface of the semiconductor chip 200. The mold layer 300 may include an insulating material. For example, the mold layer 300 may include an epoxy molding compound (EMC).

FIG. 18 is a sectional view illustrating a semiconductor package according to one or more embodiments of the present disclosure.

Referring to FIG. 18, a package substrate 400 may be provided. The package substrate 400 may include a printed circuit board (PCB) which includes signal patterns provided on a top surface of the package substrate 400.

The package substrate 400 may include substrate pads 402 provided on the top surface of the package substrate 400. The substrate pads 402 may be pads that are electrically connected to an interposer substrate 100, which will be described below.

Outer terminals 405 may be disposed below the package substrate 400. The outer terminals 405 may include solder balls or solder bumps, and the semiconductor package may be classified into a ball grid array (BGA), fine ball-grid array (FBGA), or land grid array (LGA), depending on the type and arrangement of the outer terminals 405.

The interposer substrate 100 may be provided on the package substrate 400. The interposer substrate 100 may be substantially the same as or similar to the wiring substrate described with reference to FIGS. 1-16.

One or more of the first wiring patterns 134, which are exposed to a region on a bottom surface of the first redistribution layer 130 of the interposer substrate 100, may correspond to lower pads of the interposer substrate 100. In one or more examples, the interposer substrate 100 may further include additional lower pads, which are provided on the bottom surface of the first redistribution layer 130 and are connected to the first wiring patterns 134. One or more of the second wiring patterns 144, which are exposed to a region on a top surface of the second redistribution layer 140 of the interposer substrate 100, may correspond to upper pads of the interposer substrate 100. In one or more examples, the interposer substrate 100 may further include additional upper pads, which are provided on the top surface of the second redistribution layer 140 and are connected to the second wiring patterns 144.

The interposer substrate 100 may be mounted on the package substrate 400. For example, the interposer substrate 100 may be mounted on the package substrate 400 using the substrate connection terminals 105 provided on the lower pads. The substrate connection terminals 105 may be connection terminals, which are used to connect the interposer substrate 100 to the package substrate 400. The substrate connection terminals 105 may connect the lower pads of the interposer substrate 100 to the substrate pads 402 of the package substrate 400. The substrate connection terminals 105 may include solder balls or solder bumps.

A first under-fill layer 106 may be provided between the interposer substrate 100 and the package substrate 400. The first under-fill layer 106 may fill a space between the interposer substrate 100 and the package substrate 400 and may enclose the substrate connection terminals 105.

A first semiconductor chip 500 may be disposed on the interposer substrate 100. The first semiconductor chip 500 may include a logic circuit. In other words, the first semiconductor chip 500 may be a logic chip. As an example, the first semiconductor chip 500 may include a graphics processing unit (GPU).

The first semiconductor chip 500 may include a chip circuit layer. The chip circuit layer may include a logic circuit. The first semiconductor chip 500 may include first chip pads 502 provided on the bottom surface of the first semiconductor chip 500. The first chip pads 502 may be electrically connected to the chip circuit layer of the first semiconductor chip 500.

The first semiconductor chip 500 may be mounted on the interposer substrate 100 in a flip chip manner. For example, the first semiconductor chip 500 may be mounted on the interposer substrate 100 using first chip terminals 505 provided on the first chip pads 502. The first chip terminals 505 may be connection terminals, which are used to connect the first semiconductor chip 500 to the interposer substrate 100. The first chip terminals 505 may connect the first chip pads 502 of the first semiconductor chip 500 to the upper pads of the interposer substrate 100. The first chip terminals 505 may include solder balls or solder bumps.

A second under-fill layer 506 may be provided between the first semiconductor chip 500 and the interposer substrate 100. The second under-fill layer 506 may fill a space between the first semiconductor chip 500 and the interposer substrate 100 and may enclose the first chip terminals 505.

A chip stack 600 may be disposed on the interposer substrate 100. The chip stack 600 may be disposed on the top surface of the interposer substrate 100.

The chip stack 600 may include a base substrate, second semiconductor chips 620 stacked on the base substrate, and an inner mold layer 630 enclosing the second semiconductor chips 620. Hereinafter, the structure of the chip stack 600 will be described in more detail.

The base substrate may be a base semiconductor chip 610. For example, the base substrate may be a wafer-level semiconductor substrate that is formed of a semiconductor material (e.g., silicon (Si)). Hereinafter, the base semiconductor chip 610 refers to the same component as the base substrate, and the same reference numeral may be used for both the base semiconductor chip and the base substrate.

The base semiconductor chip 610 may include a base circuit layer 612 and base penetration electrodes 614. The base circuit layer 612 may be provided on the bottom surface of the base semiconductor chip 610. The base circuit layer 612 may include an integrated circuit. For example, the base circuit layer 612 may be a memory circuit. For example, the base semiconductor chip 610 may be a memory chip (e.g., DRAM, SRAM, MRAM, or FLASH memory chips). In one or more examples, the base semiconductor chip 610 may be a logic chip. The base penetration electrodes 614 may be provided to vertically penetrate the base semiconductor chip 610. The base penetration electrodes 614 and the base circuit layer 612 may be electrically connected to each other. The bottom surface of the base semiconductor chip 610 may be an active surface. In one or more embodiments, the base substrate may be a wiring substrate, in which the base semiconductor chip 610 is not provided.

The second semiconductor chip 620 may be mounted on the base semiconductor chip 610. The second semiconductor chip 620 and the base semiconductor chip 610 may be provided to form a chip-on-wafer (COW) structure. A width of the second semiconductor chip 620 may be smaller than a width of the base semiconductor chip 610.

The second semiconductor chip 620 may include a chip circuit layer 622 and chip penetration electrodes 624. The chip circuit layer 622 may include a memory circuit. For example, the second semiconductor chip 620 may be a memory chip (e.g., DRAM, SRAM, MRAM, or FLASH memory chips). The chip circuit layer 622 may include the same circuit as the base circuit layer 612, but the present disclosure is not limited to this example. The chip penetration electrodes 624 may be provided to vertically penetrate the second semiconductor chip 620. The chip penetration electrodes 624 and the chip circuit layer 622 may be electrically connected to each other. A bottom surface of the second semiconductor chip 620 may be an active surface.

The second semiconductor chip 620 may be bonded to the base semiconductor chip 610. For example, the pads of the chip circuit layer 622 of the second semiconductor chip 620 may be in contact with top surfaces of the base penetration electrodes 614, which are exposed to a region on the top surface of the base semiconductor chip 610. In one or more examples, the second semiconductor chip 620 may be mounted on the top surfaces of the base penetration electrodes 614 using terminals provided on the pads of the chip circuit layer 622.

In one or more embodiments, a plurality of second semiconductor chips 620 may be provided. For example, a plurality of second semiconductor chips 620 may be stacked on the base semiconductor chip 610. In one or more embodiments, 4 to 32 second semiconductor chips 620 may be stacked. In one or more examples, the uppermost one of the second semiconductor chips 620 may not include the chip penetration electrodes 624. In addition, the uppermost one of the second semiconductor chips 620 may be thicker than other second semiconductor chips 620 therebelow. In one or more examples, at least one of the second semiconductor chips 620 may be different from the other second semiconductor chips 620.

Adjacent ones of the second semiconductor chips 620 may be bonded to each other. For example, a pad of the chip circuit layer 622 of each of the second semiconductor chips 620 may be in contact with a top surface of the chip penetration electrode 624, which is placed therebelow and is exposed to a region on the top surface of the second semiconductor chip 620. In one or more examples, the second semiconductor chips 620 may be mounted on the top surfaces of the chip penetration electrodes 624 using terminals provided on the pads of the chip circuit layer 622.

The inner mold layer 630 may be disposed on the top surface of the base semiconductor chip 610. The inner mold layer 630 may cover the base semiconductor chip 610 and may enclose the second semiconductor chips 620. The top surface of the inner mold layer 630 may be coplanar with the top surface of the uppermost second semiconductor chip 620, and the uppermost one of the second semiconductor chips 620 may be exposed from the inner mold layer 630. The inner mold layer 630 may include an insulating polymer material (e.g., an epoxy molding compound (EMC)).

Second chip terminals 602 may be provided on the bottom surface of the chip stack 600 (i.e., the bottom surface of the base circuit layer 612). The chip stack 600 may be coupled to the upper pads of the interposer substrate 100 through the second chip terminals 602.

A third under-fill layer 606 may be provided between the chip stack 600 and the interposer substrate 100. The third under-fill layer 606 may fill a space between the chip stack 600 and the interposer substrate 100 and may enclose the second chip terminals 602.

An outer mold layer 300 may be provided on the interposer substrate 100. The outer mold layer 300 may cover the top surface of the interposer substrate 100. The outer mold layer 300 may be provided to enclose the first semiconductor chip 500 and the chip stack 600. The top surface of the outer mold layer 300 may cover the top surface of the first semiconductor chip 500. The top surface of the outer mold layer 300 may expose the top surface of the chip stack 600. The outer mold layer 300 may include an insulating material. For example, the outer mold layer 300 may include an epoxy molding compound (EMC).

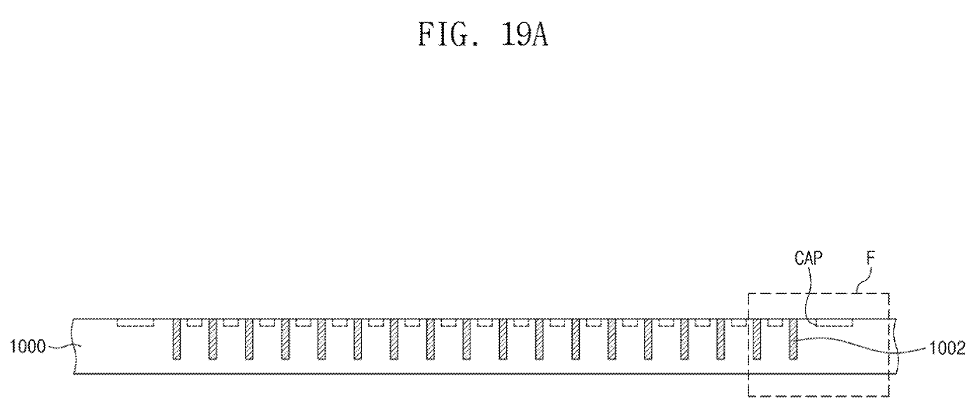

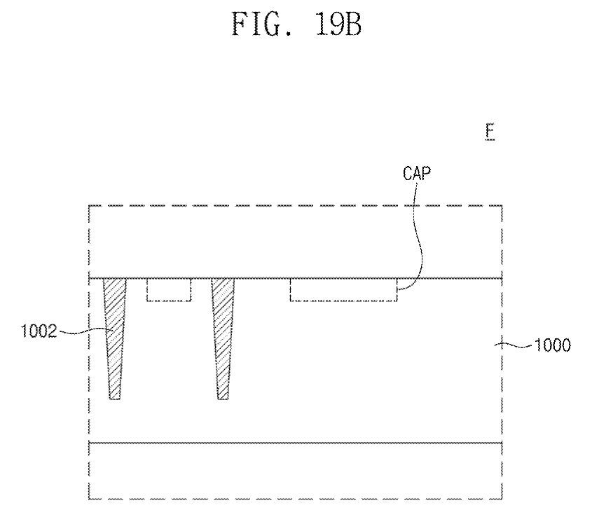

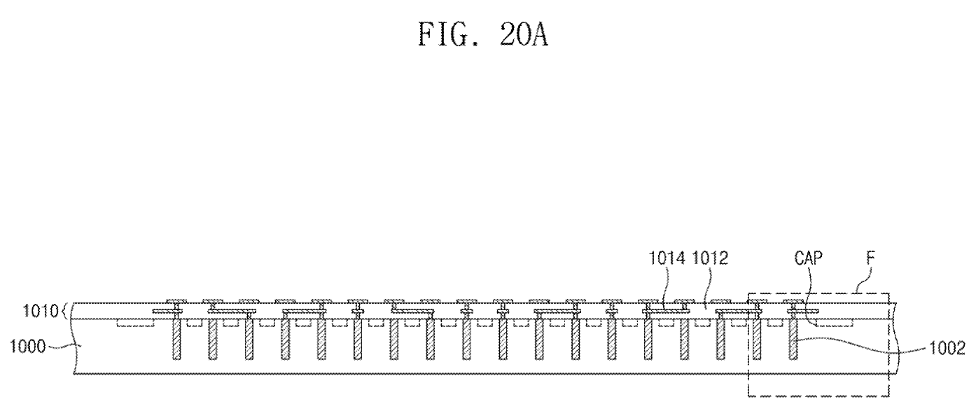

FIGS. 19A-22A are sectional views illustrating a method of fabricating a wiring substrate according to one or more embodiments of the present disclosure. FIGS. 19B-22B are enlarged sectional views illustrating portions ‘F’ of FIGS. 19A-22A.

Referring to FIGS. 19A and 19B, a core layer may be provided. The core layer may be formed on a wafer 1000. In one or more embodiments, a plurality of core layers (e.g., the first and second core layers described with reference to FIGS. 1-18) may be formed using the wafer. Hereinafter, for convenience in description, a process of forming a single core layer will be described in more detail as an example. The wafer 1000 may be a semiconductor wafer. The wafer 1000 may have a first surface and a second surface, which are opposite to each other.

Penetration holes may be formed in the wafer 1000. The penetration holes may be extended from the first surface of the wafer 1000 into the wafer 1000. In one or more examples, the penetration holes may not be exposed to the outside near the second surface of the wafer 1000. The penetration holes may not fully penetrate the wafer 1000 in the vertical direction. The penetration holes may be formed to partially penetrate the wafer 1000. The penetration holes may have a tapered structure, with its width decreasing as a distance from the top surface of the wafer 1000 increases.

Vias 1002 may be formed by filling the penetration holes with a conductive material. The vias 1002 may be exposed to a region on the first surface of the wafer 1000. The vias 1002 may not be exposed to the region on the second surface of the wafer 1000.

Capacitors CAP may be formed on the top surface of the wafer 1000. The capacitors CAP may be formed by a typical fabrication process. For example, recesses may be formed in the first surface of the wafer 1000, and then, a first electrode, a dielectric material, and a second electrode constituting the capacitors CAP may be formed in the recesses. The capacitors CAP may be formed to be horizontally spaced apart from the vias 1002. As an example, the recesses, in which the capacitors CAP are provided, may be horizontally spaced apart from the vias 1002.

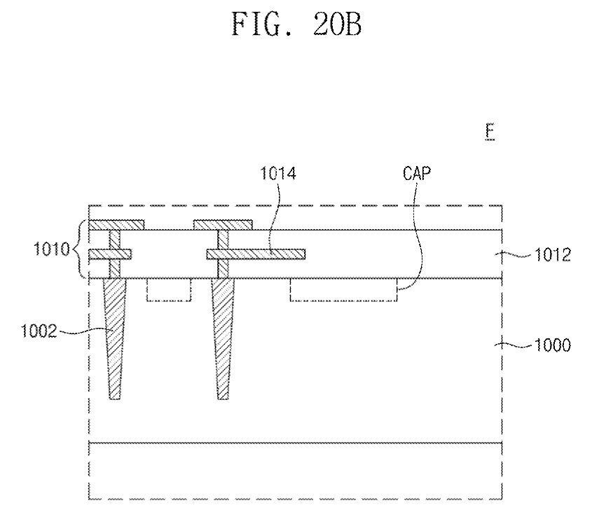

Referring to FIGS. 20A and 20B, a redistribution layer 1010 may be formed on the wafer 1000. For example, an insulating material may be deposited on the first surface of the wafer 1000, and then, a patterning process may be performed on the insulating material to form an insulating pattern 1012. The vias 1002 and the capacitors CAP, which are formed in the wafer 1000, may be exposed by the patterning process. A conductive material may be deposited on the insulating pattern 1012, and then, a patterning process may be performed on the conductive material to form wiring patterns 1014. The wiring patterns 1014 may be connected to the vias 1002 and the capacitors CAP. The above processes may be repeated to form the redistribution layer 1010.

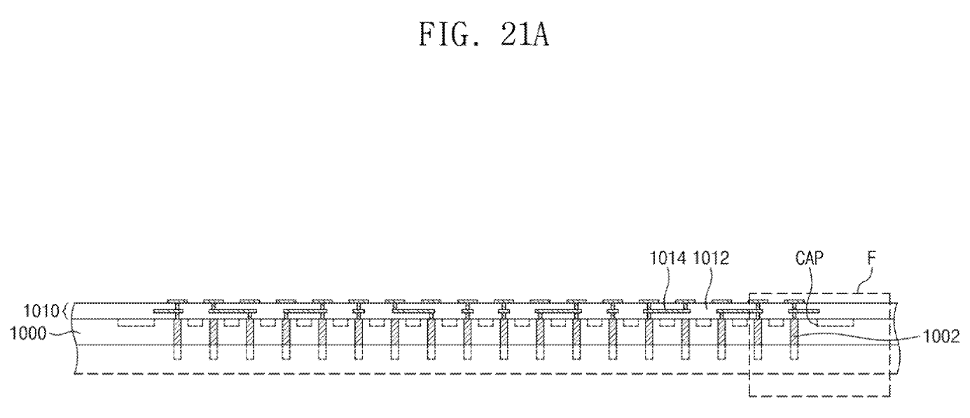

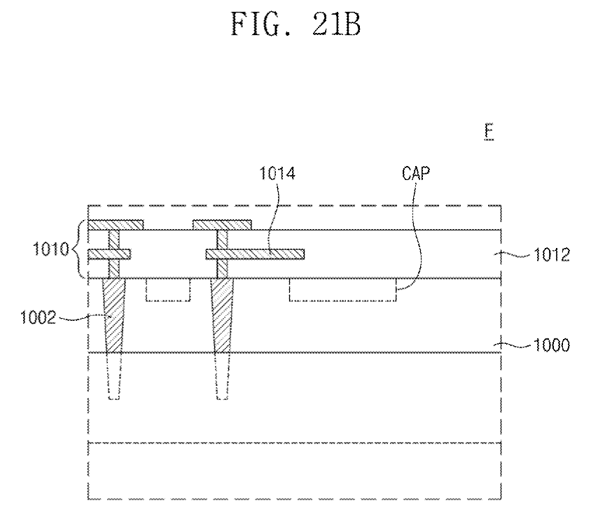

Referring to FIGS. 21A and 21B, a thinning process may be performed on the second surface of the wafer 1000. Bottom surfaces of the vias 1002 may be exposed by the thinning process. The thinning process may be performed until the wafer 1000 has a desired thickness. Lower portions of the vias 1002 may be removed during the thinning process. As the thinning process progresses, the width of the bottom surfaces of the vias 1002 may gradually increase, due to the tapered shape of the vias 1002. The thinning process may be performed until the vias 1002 have a desired width. The thinning process may include a chemical mechanical polishing (CMP) process.

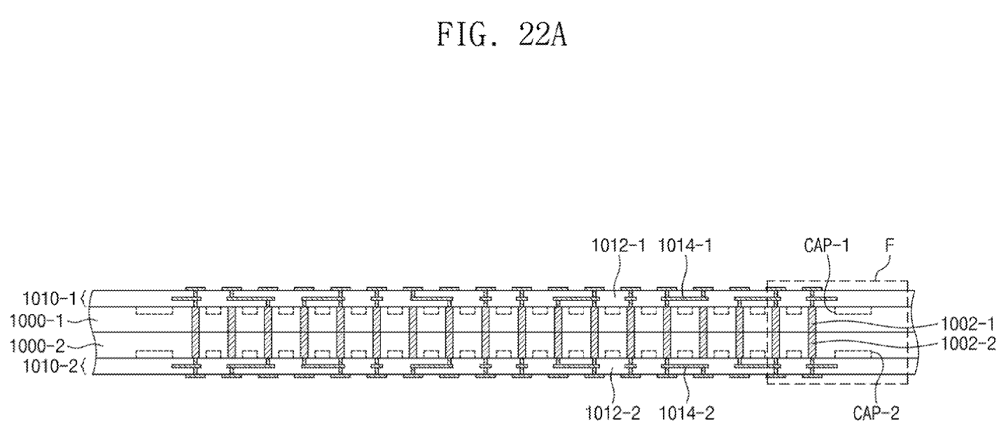

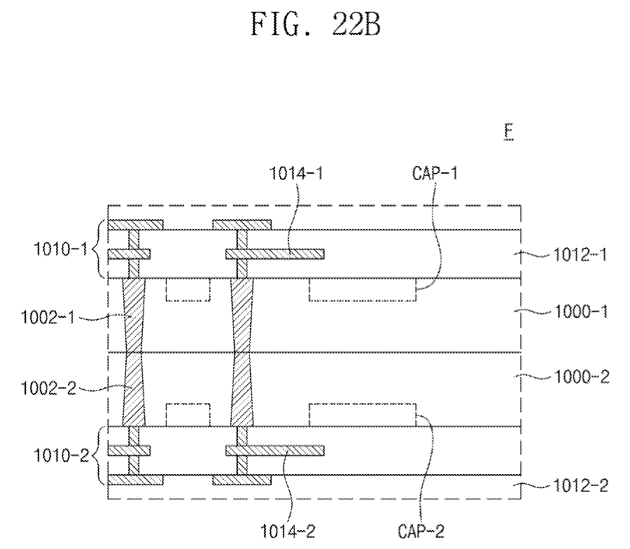

Referring to FIGS. 22A and 22B, a plurality of structures may be formed by the process described with reference to FIGS. 19A-21A and 19B-21B, and here, each of the structures may include the wafer 1000, which includes the vias 1002 and the capacitors CAP, and the redistribution layer 1010, which is provided on the wafer 1000. Two of the structures may be bonded to each other. Hereinafter, for convenience in description, a wafer, vias, capacitors, a redistribution layer, an insulating pattern, and wiring patterns, which are placed at an upper level, will be referred to as a first wafer 1000-1, first vias 1002-1, first capacitors CAP1, a first redistribution layer 1010-1, a first insulating pattern 1012-1, and first wiring patterns 1014-1. A wafer, vias, capacitors, a redistribution layer, an insulating pattern, and wiring patterns, which are placed at a lower level, will be referred to as a second wafer 1000-2, second vias 1002-2, second capacitors CAP2, a second redistribution layer 1010-2, a second insulating pattern 1012-2, and second wiring patterns 1014-2.

The second surface of the first wafer 1000-1 may face the second surface of the second wafer 1000-2. The first redistribution layer 1010-1 and the second redistribution layer 1010-2 may be spaced apart from each other, with the first wafer 1000-1 and the second wafer 1000-2 interposed therebetween. The second surface of the first wafer 1000-1 and the second surface of the second wafer 1000-2 may be in contact with each other. The first vias 1002-1 and the second vias 1002-2 may be vertically aligned to each other. The first vias 1002-1 and the second vias 1002-2 may be in contact with each other.

The first wafer 1000-1 and the second wafer 1000-2 may be bonded to each other. The first wafer 1000-1 and the second wafer 1000-2 may be bonded in a wafer-to-wafer manner.

A thermal treatment process may be performed on the first wafer 1000-1 and the second wafer 1000-2. As a result of the thermal treatment process, the first vias 1002-1 and the second vias 1002-2 may be bonded to each other. For example, the first vias 1002-1 and the second vias 1002-2 may be bonded to form a single object. The bonding of the first vias 1002-1 and the second vias 1002-2 may be naturally achieved. For example, the first vias 1002-1 and the second vias 1002-2 may be formed of the same material (e.g., copper (Cu) and so forth). The first vias 1002-1 and the second vias 1002-2 may be bonded by an inter-metal hybrid bonding process, which is enabled by surface activation at the interface where the first and second vias 1002-1 and 1002-2 are in contact. To facilitate the bonding process of the first vias 1002-1 and the second vias 1002-2, the first wafer 1000-1 and the second wafer 1000-2 may be brought into close contact with each other.

Next, a sawing process may be performed on the first wafer 1000-1 and the second wafer 1000-2, if necessary.

When holes for the vias are formed in wafers, a width of the hole may decrease as a depth increases. Thus, there may be a limitation on the aspect ratio of the vias formed in the holes. However, according to one or more embodiments of the present disclosure, the core structure, which is located between the first and second redistribution layers 1010-1 and 1010-2, may be composed of two layers (e.g., the first wafer 1000-1 and the second wafer 1000-2). The first and second wafers 1000-1 and 1000-2 may be formed to have a small thickness. Since the first vias 1002-1 and the second vias 1002-2 are formed in the first and second wafers 1000-1 and 1000-2 and are vertically bonded to each other, the via structures fully penetrating the first and second wafers 1000-1 and 1000-2 may be formed to have a small width and a large length. Thus, according to one or more embodiments of the present disclosure, it may be possible to increase the integration density of the via structures in the wiring substrate.

In addition, to expose the vias through two opposite surfaces of the wafer in the process of forming the vias in the wafer, a thinning process may be performed on each surface of the wafer. Thus, there may be a difficulty in forming devices (e.g., the capacitor), on one surface of the wafer. However, according to one or more embodiments of the present disclosure, the devices (e.g., the capacitors) may be formed on opposite surfaces of the wafers bonded to each other, and as a result, the devices may be provided on two opposite surfaces of the core structure. Accordingly, it may be possible to increase the number of the devices which can be provided in the wiring substrate. This may make it possible to increase the integration density of the wiring substrate and improve the electrical characteristics of the wiring substrate.

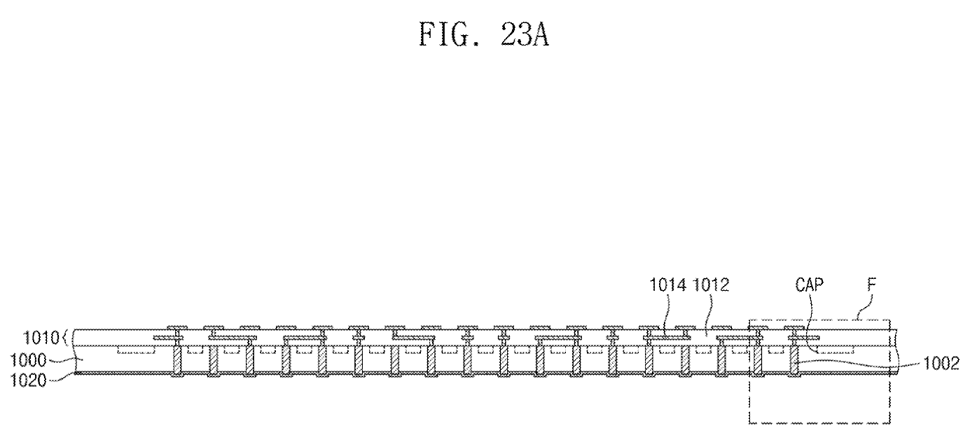

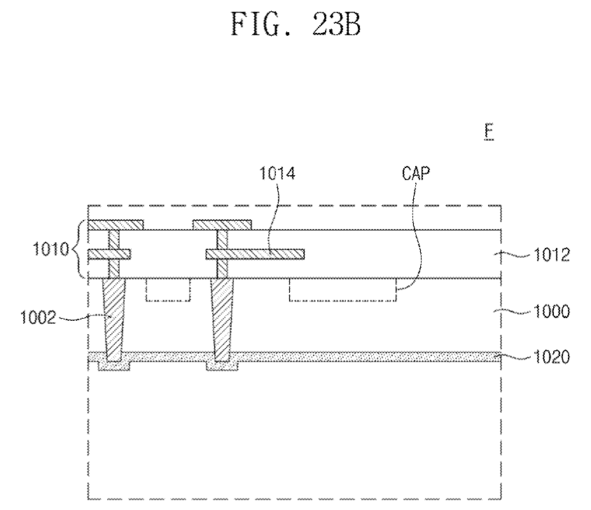

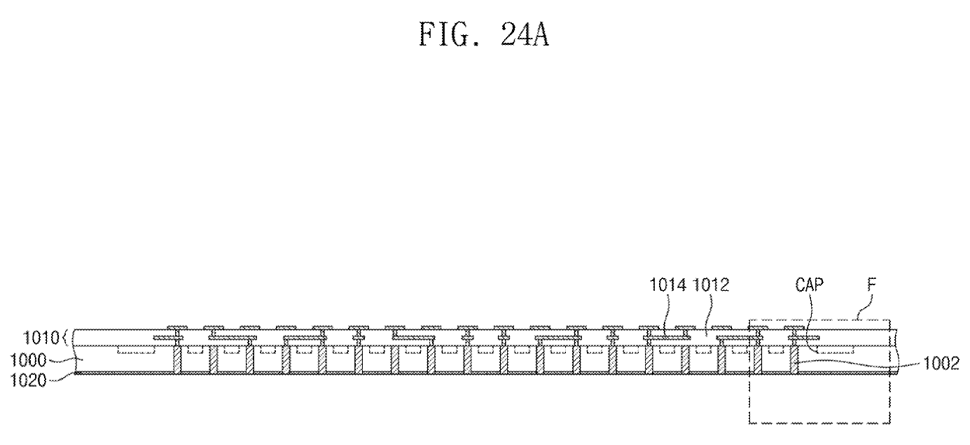

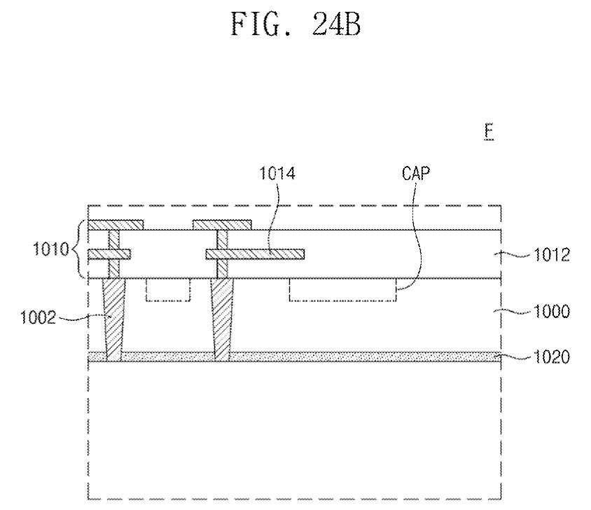

FIGS. 23A and 24A are sectional views illustrating a method of fabricating a wiring substrate according to one or more embodiments of the present disclosure. FIGS. 23B and 24B are enlarged sectional views illustrating portions ‘F’ of FIGS. 23A and 24A.

Referring to FIGS. 23A and 23B, a thinning process may be performed on the structure of FIGS. 20A and 20B (e.g., on the second surface of the wafer 1000). As a result of the thinning process, the bottom surfaces of the vias 1002 may be exposed to the outside. The thinning process may be performed in the same manner as that described with reference to FIGS. 21A and 21B. After the thinning process, the vias 1002 may protrude relative to the second surface of the wafer 1000. This may result from a difference in etch rate between the wafer 1000 and the vias 1002.

An insulating layer 1020 may be formed on the second surface of the wafer 1000. The insulating layer 1020 may be formed by performing an oxidation process, a nitridation process, or an oxidation-nitridation process on the second surface of the wafer 1000. For example, a portion adjacent to the second surface of the wafer 1000 may form the insulating layer 1020, which is formed of oxide, nitride, or oxynitride.

Referring to FIGS. 24A and 24B, a planarization process may be performed on the insulating layer 1020. The bottom surfaces of the vias 1002 may be exposed to the outside by the planarization process. The planarization process may include a chemical mechanical polishing (CMP) process.

Next, as described with reference to FIGS. 22A and 22B, structures may be formed to include the wafer 1000, which includes the vias 1002, the capacitors CAP, and the insulating layer 1020, and the redistribution layer 1010, which is provided on the wafer 1000. Two of the structures may be bonded to each other. In one or more examples, the insulating layers 1020, which are respectively included in two adjacent ones of the wafers 1000, may be in contact with each other. Thereafter, the insulating layers 1020 may be bonded to form a single object. The insulating layers 1020 may be bonded to each other to form an interface layer interposed between the wafers 1000.

A thermal treatment process may be performed on the first wafer 1000-1 and the second wafer 1000-2. As a result of the thermal treatment process, the first vias 1002-1 and the second vias 1002-2 may be bonded to each other.

Next, a sawing process may be performed on the first wafer 1000-1 and the second wafer 1000-2, if necessary.

According to one or more embodiments of the present disclosure, a wiring substrate may include via structures having a high aspect ratio. A horizontal distance between the via structures may be reduced, and an integration density of the via structures in the wiring substrate may be increased. Thus, it may be possible to provide a wiring substrate with improved electrical characteristics and a high wire density and a semiconductor package including the same.

The via structures in the wiring substrate may be provided to have a small width, and an occupying area of the via structures in a core layer may be reduced. Accordingly, it may be possible to increase the number of the capacitors in the first core layer and/or to improve electrical characteristics of the wiring substrate. Furthermore, since the capacitors are provided on both surfaces of the core structure, it may be possible to increase the number of the capacitors, which can be placed in the wiring substrate, and/or to improve the electrical characteristics of the wiring substrate.

According to one or more embodiments of the present disclosure, a method of fabricating a wiring substrate may include forming a first via in a first substrate, the first via extending from a first surface of the first substrate into the first substrate; forming a first capacitor on the first surface of the first substrate; forming a first redistribution layer on the first surface of the first substrate; performing a first thinning process on a second surface of the first substrate opposite to the first surface to expose the first via; forming a second via in a second substrate, the second via extending from a third surface of the second substrate into the second substrate; forming a second capacitor on the third surface of the second substrate; forming a second redistribution layer on the third surface of the second substrate; performing a second thinning process on a fourth surface of the second substrate opposite to the third surface to expose the second via; and bonding the first substrate to the second substrate in such a way that the second surface faces the fourth surface. After the bonding of the first substrate to the second substrate, the first via and the second via may be connected to each other.

In one or more embodiments, a width of the first via may decrease as a distance from the first surface increases in a direction toward the second surface. A width of the second via may decrease as a distance from the third surface increases in a direction toward the fourth surface.

In one or more embodiments, after the bonding of the first substrate to the second substrate, a width of the first via on a contact surface between the first via and the second via may be larger than a width of the second via.

In one or more embodiments, a thickness of the first substrate after the first thinning process may be smaller than a thickness of the second substrate after the second thinning process. A width of the first via on the first surface may be equal to a width of the second via on the third surface.

In one or more embodiments, a thickness of the first substrate after the first thinning process may be substantially equal to a thickness of the second substrate after the second thinning process. A width of the first via on the first surface may be larger than a width of the second via on the third surface.

In one or more embodiments, the bonding of the first substrate to the second substrate may include bonding the first via to the second via. On a contact surface between the first via and the second via, the first via and the second via may form a single object that is formed of the same material.

In one or more embodiments, before the bonding of the first substrate to the second substrate, the method may further include forming a first insulating layer on the second surface of the first substrate and forming a second insulating layer on the fourth surface of the second substrate. The bonding of the first substrate to the second substrate may include bonding the first insulating layer to the second insulating layer.

In one or more embodiments, the first insulating layer may be formed by performing an oxidation process, a nitridation process, or an oxidation-nitridation process on the second surface of the first substrate. The second insulating layer may be formed by performing an oxidation process, a nitridation process, or an oxidation-nitridation process on the fourth surface of the second substrate.

In one or more embodiments, the bonding of the first insulating layer to the second insulating layer may be performed in such a way that the first insulating layer and the second insulating layer are bonded to form a single object.

In one or more embodiments, the first substrate and the second substrate may be provided on a single wafer.

While example embodiments of the present disclosure have been particularly shown and described, it will be understood by one of ordinary skill in the art that variations in form and detail may be made therein without departing from the spirit and scope of the attached claims.

What is claimed is:

1. A wiring substrate, comprising:
a first redistribution layer;
a first core layer;
a second core layer; and
a second redistribution layer, which are sequentially stacked;
a first capacitor on a first surface of the first core layer; and
a second capacitor on a first surface of the second core layer,
wherein the first core layer comprises a first via, which penetrates the first core layer and is connected to the first redistribution layer,
wherein the second core layer comprises a second via, which penetrates the second core layer and is connected to the second redistribution layer,
wherein the first via and the second via are in contact with each other between the first core layer and the second core layer,
wherein the first capacitor is in a first recess, which is in the first surface of the first core layer and is on one side of the first via, and
the second capacitor is in a second recess, which is in the first surface of the second core layer and is on one side of the second via.

2. The wiring substrate of claim 1, wherein each of the first capacitor and the second capacitor comprises:
a first electrode and a second electrode spaced apart from each other;
a dielectric material filling a space between the first electrode and the second electrode; and
at least one first sub-electrode and at least one second sub-electrode, which are alternately between the first electrode and the second electrode,
wherein the at least one first sub-electrode is connected to the first electrode, and
wherein the at least one second sub-electrode is connected to the second electrode.

3. The wiring substrate of claim 1, wherein a second surface of the first core layer is in contact with a second surface of the second core layer, and
wherein a contact surface between the first via and the second via is placed at substantially a same vertical level as a contact surface between the first core layer and the second core layer.

4. The wiring substrate of claim 1, further comprising an interface layer between the first core layer and the second core layer,
wherein a contact surface between the first via and the second via is placed within the interface layer.

5. The wiring substrate of claim 1, wherein a width of the first via decreases as a distance from the first surface of the first core layer increases in a direction toward a second surface of the first core layer, and
wherein a width of the second via decrease as a distance from the first surface of the second core layer increases in a direction toward a second surface of the second core layer.

6. The wiring substrate of claim 1, wherein, on a contact surface between the first via and the second via, a width of the first via is larger than a width of the second via.

7. The wiring substrate of claim 6, wherein a width of the first via on the first surface of the first core layer is larger than a width of the second via on the first surface of the second core layer, and
wherein a thickness of the first core layer is substantially equal to a thickness of the second core layer.

8. The wiring substrate of claim 6, wherein a width of the first via on the first surface of the first core layer is substantially equal to a width of the second via on the first surface of the second core layer, and
wherein a thickness of the first core layer is smaller than a thickness of the second core layer.

9. The wiring substrate of claim 1, wherein, on a contact surface between the first via and the second via, the first via and the second via form a single object that comprises a same material.

10. A semiconductor package, comprising:
a substrate;
a semiconductor chip disposed on the substrate; and
a mold layer provided on the substrate to cover the semiconductor chip,
wherein the substrate comprises:
a first redistribution layer;
a first core layer on the first redistribution layer, the first core layer comprising a first via penetrating the first core layer;
a second core layer on the first core layer, the second core layer comprising a second via penetrating the second core layer;
a second redistribution layer on the second core layer;
a first capacitor between the first redistribution layer and the first core layer; and
a second capacitor between the second redistribution layer and the second core layer,
wherein a width of the first via decreases as a distance from the first redistribution layer increases,
wherein a width of the second via decreases as a distance from the second redistribution layer increases, and
wherein, on a contact surface between the first via and the second via, the first via and the second via form a single object that comprises a same material.

11. The semiconductor package of claim 10, wherein the first capacitor is in a first recess, which is formed in a first surface of the first core layer and is on one side of the first via, and
wherein the second capacitor is in a second recess, which is in a first surface of the second core layer and is on one side of the second via.

12. The semiconductor package of claim 11, wherein each of the first capacitor and the second capacitor comprises:
a first electrode and a second electrode spaced apart from each other;
a dielectric material filling a space between the first electrode and the second electrode; and
at least one first sub-electrode and at least one second sub-electrode, which are alternately between the first electrode and the second electrode,
wherein the at least one first sub-electrode is connected to the first electrode, and
wherein the at least one second sub-electrode is connected to the second electrode.

13. The semiconductor package of claim 10, wherein the first capacitor is on a first surface of the first core layer,
wherein the first redistribution layer covers the first capacitor on the first surface of the first core layer,
wherein the second capacitor is on a first surface of the second core layer, and
wherein the second redistribution layer covers the second capacitor on the first surface of the second core layer.

14. The semiconductor package of claim 13, wherein each of the first capacitor and the second capacitor comprises:
a first electrode and a second electrode spaced apart from each other; and
a dielectric material filling a space between the first electrode and the second electrode,
wherein at least one of the first electrode and the second electrode of the first capacitor is a portion of wiring patterns of the first redistribution layer,
wherein at least one of the first electrode and the second electrode of the second capacitor is a portion of wiring patterns of the second redistribution layer.

15. The semiconductor package of claim 10, wherein a second surface of the first core layer is in contact with a second surface of the second core layer, and
wherein the contact surface between the first via and the second via is at a same plane as a contact surface between the first core layer and the second core layer.

16. The semiconductor package of claim 10, further comprising an interface layer between the first core layer and the second core layer,
wherein the contact surface between the first via and the second via is within the interface layer.

17. The semiconductor package of claim 10, wherein, on the contact surface between the first via and the second via, a width of the first via is larger than a width of the second via,
wherein a width of the first via on a first surface of the first core layer is larger than a width of the second via on a first surface of the second core layer, and
wherein a thickness of the first core layer is substantially equal to a thickness of the second core layer.

18. The semiconductor package of claim 10, wherein, on the contact surface between the first via and the second via, a width of the first via is larger than a width of the second via,
wherein a width of the first via on a first surface of the first core layer is substantially equal to a width of the second via on a first surface of the second core layer, and
wherein a thickness of the first core layer is smaller than a thickness of the second core layer.

19. A semiconductor package, comprising:
a package substrate;
an interposer substrate on the package substrate; and
a first semiconductor chip and a chip stack on the interposer substrate and spaced apart from each other in a first direction,
wherein the chip stack comprises second semiconductor chips which are stacked in a second direction,
wherein the interposer substrate comprises a first redistribution layer, a core structure, and a second redistribution layer which are sequentially stacked,
wherein the core structure comprises:
a first core layer, an interface layer, and a second core layer, which are sequentially stacked;
a first via, which penetrates the first core layer and is coupled to the first redistribution layer;
a second via, which penetrates the second core layer and is coupled to the second redistribution layer;
a first capacitor, which is between the first core layer and the first redistribution layer and is spaced apart from the first via in the first direction; and
a second capacitor, which is between the second core layer and the second redistribution layer and is spaced apart from the second via in the first direction,
wherein a contact surface between the first via and the second via is placed within the interface layer,
wherein, on the contact surface between the first via and the second via, a width of the first via is larger than a width of the second via.

20. The semiconductor package of claim 19, wherein a width of the first via on a first surface of the first core layer is substantially equal to a width of the second via on a top surface of the second core layer, and
wherein a thickness of the first core layer is smaller than a thickness of the second core layer.
